(19) United States
(12) Patent Application Publication
(10) Pub. No.: US 2008/0102642 A1
(43) Pub. Date: May 1, 2008

(54) METHOD OF SEASONING IDLE SILICON NITRIDE ETCHER AND METHOD OF ACTIVATING

(75) Inventors: Ping-Hung Chen, Kaohsiung County (TW); Kuang-Hua Shih, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNITED MICROELECTRONICS CORP., Hsinchu City (TW)

(21) Appl. No.: 11/554,599

(22) Filed: Oct. 31, 2006

(51) Int. Cl. H01L 21/461; H01L 21/302

(52) U.S. Cl. 438/706; 438/718; 438/724; 438/744; 438/745

(57) ABSTRACT

A method of seasoning an idle silicon nitride etcher is described. A buffer material having stronger adhesion to an internal wall of the chamber of the silicon nitride etcher than silicon nitride is etched in the chamber, so as to form a buffer layer on the internal wall of the chamber. Then, silicon nitride is etched in the chamber to form a layer of SiN-based polymer on the buffer layer.

### BACKGROUND OF THE INVENTION

1. Field of Invention

This invention relates to an integrated circuit (IC) process, and more particularly to a method of seasoning an idle silicon nitride etcher and to a method of activating a silicon nitride etcher that utilizes the method of seasoning an idle silicon nitride etcher.

2. Description of Related Art

As the linewidth of IC process is much reduced, the damage caused by a particle is greater, so that controlling the number of particles is important in advanced processes. The particle sources in an IC process include the etchers used for etching different films, and the particles in an etcher mainly result from the etching residues accumulated in previous use. Therefore, a preventive maintenance (PM) of an etcher usually includes cleaning the inside of the chamber of the etcher thoroughly.

However, cleaning of the chamber of an etcher is not frequently conducted for consuming too much time, so that the particle number cannot be reduced effectively. One method to solve this problem is to use reactive gas to remove the etching residues after a period of use, as described in U.S. Pat. No. 6,699,399, but the method easily damages the internal wall of the chamber.

Another method is to season the etcher with etching of the material to be etched. For example, to season a silicon nitride etcher, it is feasible to etch silicon nitride in the chamber to form a layer of SiN-based polymer on the internal wall of the chamber. Because the layer of SiN-based polymer layer has a composition similar to that of the SiN etching residue in the regular production and is formed substantially uniform in the thickness, the SiN etching residue formed in later use of the etcher easily adheres to the SiN-based polymer layer and causes less stress on the internal wall. Thus, less SiN-based polymer peels off from the internal wall so that the particle number is decreased.

Nevertheless, since the chamber wall usually includes a metallic material, the SiN-based polymer layer is not deposited so well on the chamber wall, so that peeling-off of the SiN-etching residue from the chamber wall is not prevented effectively and the particle number is not reduced effectively.

### SUMMARY OF THE INVENTION

In view of the foregoing, this invention provides a method of seasoning an idle silicon nitride etcher, which can further reduce the number of particles in the chamber.

This invention also provides a method of activating a silicon nitride etcher, which utilizes the method of seasoning an idle silicon nitride etcher of this invention.

The method of seasoning an idle silicon nitride etcher of this invention is described as follows. A buffer material having stronger adhesion to an internal wall of the chamber of the silicon nitride etcher than silicon nitride is etched in the chamber, so as to form a buffer layer on the internal wall of the chamber. Then, silicon nitride is etched in the chamber to form a layer of SiN-based polymer on the buffer layer.

The method of activating a silicon nitride etcher of this invention is described as follows. The silicon nitride etcher is maintained, and then a buffer material having stronger adhesion to an internal wall of the chamber of the etcher than silicon nitride is etched in the chamber, so as to form a buffer layer on the internal wall of the chamber. Thereafter, silicon nitride is etched in the chamber to form a layer of SiN-based polymer on the buffer layer on the internal wall of the chamber.

In a preferred embodiment, the internal wall includes aluminum, and the buffer material is silicon oxide, which has stronger adhesion to aluminum than silicon nitride.

Since a buffer layer, which is based on a buffer material with stronger adhesion to the internal wall of the chamber than silicon nitride, is formed between the internal wall and the layer of SiN-based polymer, the SiN-based polymer layer is bound firmly on the internal wall to inhibit peeling-off of the SiN etching residue more effectively, so that less particles are caused.

In order to make the aforementioned and other objects, features and advantages of the present invention comprehensible, a preferred embodiment accompanied with figures is described in detail below.

### BRIEF DESCRIPTION OF THE DRAWINGS

FIGS. 1A and 1B illustrate a process flow of the method of seasoning an idle silicon nitride etcher according to an embodiment of this invention.

### DESCRIPTION OF EMBODIMENTS

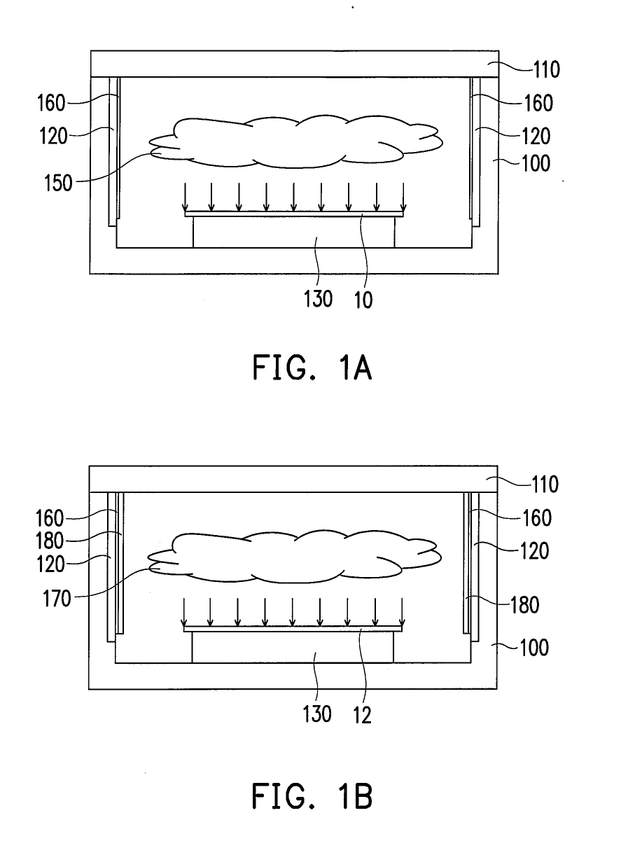

An embodiment of this invention is provided as follows to further explain this invention, which is not intended to limit the scope of this invention. FIGS. 1A and 1B show a process flow of the method of seasoning an idle silicon nitride etcher according to the embodiment of this invention.

Referring to FIG. 1A, the etcher to be seasoned in this embodiment includes a chamber 100, a cover 110 of the chamber 100, a liner 120 as an internal wall of the chamber 110 and a chuck 130 for holding a wafer. In an AMAT SiN spacer etcher manufactured by Applied Material Inc., the liner 120 is an aluminum liner. The etcher is also equipped with a RF generator, gas inlets, a gas outlet, a pump and so forth, which are not shown in these figures as being well known to one of ordinary skill in the art.

The etcher may alternatively be one for etching a silicon nitride layer as a hard mask layer over a semiconductor substrate in a shallow trench isolation (STI) process. In fact, the seasoning method of this invention can be readily applied to any SiN etcher that suffers from particles due to poor adhesion between the chamber wall and the SiN-based polymer as the etching residue.

The silicon nitride etcher may have been subjected to a preventive maintenance or have experienced an inline process idle period, wherein the preventive maintenance may include replacing the RF generator that usually has a lifetime of 60±10 hours, using an acid or a solvent to remove the etching residues on the internal wall of the chamber, and so forth. Other operations usually conducted in a preventive maintenance of a SiN etcher can be discovered in the related arts.

To season the etcher, firstly, a plurality of wafers 10 having thereon a layer of a buffer material with stronger adhesion to the liner 120 than silicon nitride are etched in sequence in the chamber 100 with plasma 150 generated above the wafers 10, so as to form a buffer layer 160 as an etching residue on the liner 120. The plasma 150 is generated by exciting the gases introduced into the chamber 100. The number of the plurality of wafers 10 is sufficient for forming a sufficiently thick buffer layer 160 on the liner 120. As the liner 120 includes aluminum, the buffer material is preferably silicon oxide, which has stronger adhesion to aluminum than silicon nitride.

When the buffer material is silicon oxide, the thickness of the silicon oxide layer on a wafer 10 usually has a thickness of 3000-4000 Å, the buffer layer 160 as a silicon oxide etching residue includes a SiO-based polymer material, and the number of the wafers 10 used for forming the buffer layer 160 is usually eight or more. Moreover, the gases for generating the plasma 150 that is effective in etching silicon oxide usually include CH₃F, CF₄ and Ar in suitable flow rates.

Referring to FIG. 1B, a plurality of wafers 12 having thereon a layer of silicon nitride are etched in sequence in the chamber 100 with plasma 170 to form a SiN-based polymer layer 180 as an etching residue on the buffer layer 160 on the liner 120. The thickness of the silicon nitride layer on a wafer 12 usually has a thickness of 1000-2000 Å. The number of the plurality of wafers 12 is sufficient for forming a SiN-based polymer layer 180 that is sufficiently thick for inhibiting generation of particles. The gases for generating the plasma 170 that is effective in etching silicon nitride usually include CH₃F, CF₄, Ar and O₂ in suitable flow rates.

In addition, the etching recipe for silicon nitride in the etching-rate (ER) raising period of the etcher may be different from that in the ER-stabilized period of the same in the above silicon nitride seasoning step to optimize the uniformity of the SiN-based polymer layer 180, wherein the etching recipe in the ER-stabilized period is normally the one used in the regular production. In an example using an AMAT SiN etcher, the etching rate in the ER-raising period raises from about 1200 Å/min to about 1600 Å/min, and the number of the wafers 12 used in the same period is about eight. The etching rate in the subsequent ER-stabilized period is about 1600 Å/min, while the number of the wafers 12 used in the same period is about 25.

Since a buffer layer, which is based on a buffer material with stronger adhesion to an internal wall of the chamber than silicon nitride, is formed between the internal wall and the layer of SiN-based polymer, the SiN-based polymer layer is bound firmly on the internal wall to inhibit peeling-off of the SiN etching residue more effectively, so that less particles are caused. In a exemplary experiment, the preventive maintenance not-good (NG, 30 or more particle sites) ratio in the particle monitor conducted after the above silicon oxide-silicon nitride seasoning steps is as low as about 2%, which is much lower than the value of 60% that is obtained in a comparative experiment with silicon nitride seasoning only.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A method of seasoning an idle silicon nitride etcher, comprising:
etching, in a chamber of the silicon nitride etcher, a buffer material with stronger adhesion to an internal wall of the chamber than silicon nitride, so as to form a buffer layer on the internal wall of the chamber;
etching silicon nitride in the chamber to form a layer of SiN-based polymer on the buffer layer.

2. The method of claim 1, wherein the internal wall of the chamber comprises aluminum.

3. The method of claim 2, wherein the internal wall of the chamber comprises an aluminum liner.

4. The method of claim 2, wherein the buffer material is silicon oxide.

5. The method of claim 1, wherein in the step of etching the buffer material, a plurality of wafers having a layer of the buffer material thereon are etched in sequence.

6. The method of claim 1, wherein in the step of etching silicon nitride, a plurality of wafers having a silicon nitride layer thereon are etched in sequence.

7. The method of claim 1, which is conducted after a preventive maintenance of the silicon nitride etcher.

8. The method of claim 1, which is conducted after an inline process idle period of the silicon nitride etcher.

9. A method of activating a silicon nitride etcher, comprising:
maintaining the silicon nitride etcher;
etching, in a chamber of the silicon nitride etcher, a buffer material with stronger adhesion to an internal wall of the chamber than silicon nitride, so as to form a buffer layer on the internal wall of the chamber; and
etching silicon nitride in the chamber to form a layer of SiN-based polymer on the buffer layer.

10. The method of claim 9, wherein the internal wall of the chamber comprises aluminum.

11. The method of claim 10, wherein the internal wall of the chamber comprises an aluminum liner.

12. The method of claim 10, wherein the buffer material is silicon oxide.

13. The method of claim 9, wherein in the step of etching the buffer material, a plurality of wafers having a layer of the buffer material thereon are etched in sequence.

14. The method of claim 9, wherein in the step of etching silicon nitride, a plurality of wafers having a silicon nitride layer thereon are etched in sequence.

15. The method of claim 9, wherein maintaining the silicon nitride etcher comprises using an acid or a solvent to remove an etching residue on the internal wall of the chamber.
